(19) United States
(12) Patent Application Publication
(10) Pub. No.: US 2025/0275125 A1
(43) Pub. Date: Aug. 28, 2025

(54) SEMICONDUCTOR STRUCTURE AND METHOD FOR FORMING SAME

(71) Applicant: CXMT Corporation, Hefei City (CN)

(72) Inventor: Yi TANG, Hefei City (CN)

(73) Assignee: CXMT Corporation, Hefei City (CN)

(21) Appl. No.: 19/206,010

(22) Filed: May 12, 2025

Related U.S. Application Data
(63) Continuation of application No. PCT/CN2023/134104, filed on Nov. 24, 2023.

(30) Foreign Application Priority Data
Jul. 31, 2023 (CN) 202310966093.2

(51) Int. Cl. H10B 12/00; H10D 1/68; H10D 64/27

(52) U.S. Cl. CPC H10B 12/488; H10B 12/05; H10D 1/714; H10D 64/514; H10D 64/518

(57) ABSTRACT

The semiconductor structure includes a substrate, word line structures, a plurality of active pillar structures, and an isolation structure. A plurality of the word line structures are located on the substrate and are spaced apart along a first direction. Each word line structure includes a plurality of gate structures spaced apart sequentially along a third direction. The active pillar structure is disposed on the outer wall of the gate structure. At least one end of the active pillar structure along a second direction is provided with a trench with an opening facing the second direction. A part of the active pillar structure surrounding the gate structure constitutes a channel structure, and a part of the active pillar structure, located on both sides of the channel structure along the second direction and adjacent to the trench, constitutes a source/drain.

### CROSS-REFERENCE TO RELATED APPLICATIONS

This application is a continuation of PCT/CN2023/134104 filed on Nov. 24, 2023, which claims priority to Chinese Patent Application No. 202310966093.2 filed on Jul. 31, 2023. The disclosures of the above-referenced applications are hereby incorporated by reference in their entirety.

### BACKGROUND

Currently, to achieve the miniaturization of semiconductor structure sizes, a Channel-All-Around (Channel-All-Around, CAA) structure is typically used as the channel structure for Indium Gallium Zinc Oxide (Indium Gallium Zinc Oxide, IGZO) transistors. However, in the CAA structures based on IGZO devices, the gate structure is relatively close to the source/drain, which makes it easy for Gate-Induced Drain Leakage (Gate-Induced Drain Leakage, GIDL) current to occur between the gate structure and the source/drain.

### SUMMARY

In view of this, the embodiments of the present disclosure provide a semiconductor structure and a method for forming the same.

The present disclosure relates to the technical field of semiconductors and relates to, but is not limited to, a semiconductor structure and a method for forming the same.

In a first aspect, an embodiment of the present disclosure provides a semiconductor structure.

The semiconductor structure includes a substrate.

The semiconductor structure includes word line structures located on the substrate and spaced apart along a first direction. Each of the word line structures includes a plurality of gate structures spaced apart sequentially along a third direction.

The semiconductor structure includes a plurality of active pillar structures disposed on the outer wall of each of the plurality of gate structures. At least one end of each of the plurality of active pillar structures along a second direction is provided with a trench with an opening facing the second direction; the part of the active pillar structure surrounding the gate structure constitutes a channel structure, and the part of the active pillar structure, located on both sides of the channel structure along the second direction and adjacent to the trench, constitutes a source/drain.

The semiconductor structure includes an isolation structure located on the inner wall of the trench adjacent to the gate structure.

The first direction intersects with the second direction and is located in the plane in which the substrate is located; the third direction intersects with the plane in which the surface of the substrate is located.

In some embodiments, the trench includes a first trench and a second trench located respectively at both ends of the active pillar structure along the second direction.

The isolation structure includes a first isolation structure and a second isolation structure.

The first isolation structure is located on the inner wall of the first trench adjacent to the gate structure, and the second isolation structure is located on the inner wall of the second trench adjacent to the gate structure.

In some embodiments, the side wall of the word line structure in a cross-section along the third direction is serrated, and the word line structure includes the gate structure and a recessed part alternately arranged sequentially along the third direction; the dimension of the gate structure along the second direction is greater than the dimension of the recessed part along the second direction, and the dimension of the gate structure along the first direction is greater than the dimension of the recessed part along the first direction.

In some embodiments, the source/drain includes a first source/drain and a second source/drain which are located at both ends of the active pillar structure along the second direction.

The part of the active pillar structure adjacent to the first trench constitutes the first source/drain, and the part of the active pillar structure adjacent to the second trench constitutes the second source/drain.

In some embodiments, the semiconductor structure further includes a bit line and a capacitor structure.

The bit line is connected to the first source/drain and is embedded in the first trench, contacting the first isolation structure.

The capacitor structure is connected to the second source/drain and is embedded in the second trench, contacting the second isolation structure.

In some embodiments, the semiconductor structure further includes a spacer layer.

The spacer layer is located between a plurality of the bit lines arranged along the third direction, between a plurality of the capacitor structures arranged along the third direction, and between a plurality of the active pillar structures arranged along the third direction.

In some embodiments, the bit line extends along the first direction, and a row of the bit lines arranged along the first direction are interconnected.

The plurality of bit lines arranged along the third direction form a staircase structure.

In a second aspect, an embodiment of the present disclosure provides a method for forming a semiconductor structure. The method includes the steps as follows.

A substrate is provided. A stacked structure is formed on the substrate; the projection of the stacked structure on the substrate is comb-shaped; the stacked structure includes a first region and a second region which are arranged along a second direction; the second region includes a plurality of sub-regions spaced apart along a first direction.

Word line structures that extend along a third direction and penetrate through the plurality of sub-regions are formed. Each of the word line structures includes a plurality of gate structures spaced apart sequentially along the third direction.

A plurality of active pillar structures that surround the plurality of gate structures and are spaced apart are formed. At least one end of each of the plurality of active pillar structures along the second direction is provided with a trench with an opening facing the second direction; the part of the active pillar structure surrounding the gate structure constitutes a channel structure, and the part of the active pillar structure, located on both sides of the channel structure along the second direction and adjacent to the trench, constitutes a source/drain.

An isolation structure on the inner wall of the trench adjacent to the gate structure is formed.

The first direction intersects with the second direction and is parallel to a plane in which the substrate is located, and the third direction is perpendicular to the plane in which the substrate surface is located.

In some embodiments, the stacked structure includes a spacer layer, a first sacrificial layer, a second sacrificial layer, and the first sacrificial layer, which are alternately and cyclically arranged along the third direction. Forming the word line structures that extend along the third direction and penetrate through the plurality of sub-regions includes the steps as follows.

Each of the plurality of sub-regions is etched to form a third trench extending along the third direction; the third trench exposes the spacer layer at the lowest level.

A first initial active pillar structure is formed on part of the inner wall of the third trench; the first initial active pillar structure is partially or fully embedded in the first sacrificial layer.

The word line structure is formed in the third trench provided with the first initial active pillar structure.

In some embodiments, forming the plurality of active pillar structures that surround the plurality of gate structures and are spaced apart includes the step as follows.

The part of the first initial active pillar structure that extends along the first direction into the space between the second sacrificial layer and the spacer layer is removed to form the active pillar structure.

The remaining part of the first initial active pillar structure embedded between the second sacrificial layer and the spacer layer constitutes the source/drain.

The region between the remaining part of the first initial active pillar structure that extends into the space between the second sacrificial layer and the spacer layer, and the first initial active pillar structure located on the side wall of the second sacrificial layer, forms the trench.

In some embodiments, the trench includes a first trench and a second trench located respectively at both ends of the active pillar structure along the second direction. The isolation structure includes a first isolation structure located on the inner wall of the first trench adjacent to the gate structure, as well as a second isolation structure located on the inner wall of the second trench adjacent to the gate structure. Forming the isolation structure on the inner wall of the trench adjacent to the gate structure includes the steps as follows.

The second sacrificial layer between the channel structures is removed to form the first trench and the second trench.

The first isolation structure and the second isolation structure are formed respectively on the inner walls of the first trench and the second trench adjacent to the gate structure.

In some embodiments, the source/drain includes a first source/drain and a second source/drain located at both ends of the active pillar structure along the second direction. The part of the active pillar structure adjacent to the first trench constitutes the first source/drain. The method further includes the steps as follows.

The second sacrificial layer in the stacked structure is removed while forming the first trench and the second trench, to form a fourth trench and a fifth trench. The fourth trench encloses the first trench, and the fifth trench encloses the second trench.

After or while forming the first isolation structure and the second isolation structure, the first sacrificial layer on one side close to the first region along the first direction in the first region and the second region is removed to form a sixth trench. The sixth trench encloses the fourth trench.

A bit line, in contact with the first source/drain, is formed in the sixth trench.

In some embodiments, the part of the active pillar structure adjacent to the second trench constitutes the second source/drain. The method further includes the steps as follows.

The remaining first sacrificial layer in the stacked structure is removed to form a seventh trench. The seventh trench encloses the fifth trench.

A capacitor structure, in contact with the second source/drain, is formed in the seventh trench.

In some embodiments, forming the first initial active pillar structure on part of the inner wall of the third trench includes the steps as follows.

A second initial active pillar structure is formed on the inner wall and the bottom of the third trench.

The second initial active pillar structure at the bottom of the third trench and on the side wall of the spacer layer is removed to form the first initial active pillar structure.

In some embodiments, etching each of the plurality of sub-regions to form the third trench extending along the third direction includes the steps as follows.

The sub-region is etched until the spacer layer at the lowest level is exposed, thereby forming an eighth trench extending along the third direction.

Through the eighth trench, lateral etching is performed to remove part of the first sacrificial layer and part of the second sacrificial layer, thereby forming the third trench. The third trench encloses the eighth trench and is serrated; the dimension of the third trench between the first sacrificial layers is greater than the dimension of the third trench between the second sacrificial layers.

The embodiments of the present disclosure provide a semiconductor structure. The semiconductor structure includes: a substrate; word line structures located on the substrate and spaced apart along a first direction, each word line structure including a plurality of gate structures spaced apart sequentially along a third direction; a plurality of active pillar structures, disposed on the outer wall of each gate structure, where at least one end of each active pillar structure along a second direction is provided with a trench with an opening facing the second direction; the part of the active pillar structure surrounding the gate structure constitutes a channel structure, and the part of the active pillar structure, located on both sides of the channel structure along the second direction and adjacent to the trench, constitutes the source/drain; and an isolation structure, located on the inner wall of the trench adjacent to the gate structure. Because at least one end of the active pillar structure along the second direction is provided with a trench with an opening facing the second direction, and the part of the active pillar structure adjacent to the trench constitutes the source/drain, such an arrangement can not only increase the distance between the gate structure and the drain, reducing the generation of GIDL, but also increase the contact area between the capacitor structure and the source/drain as well as between the bit line and the source/drain. This can reduce contact resistance and improve the response speed of the semiconductor structure. In addition, because the inner wall of the trench adjacent to the gate structure is provided with an isolation structure, such an arrangement can not only further reduce GIDL but also reduce the parasitic capacitance between the gate structure and the capacitor structure and between the gate structure and the bit line, thereby reducing the power consumption of the semiconductor structure.

### BRIEF DESCRIPTION OF THE DRAWINGS

In the drawings (may not necessarily be drawn to scale), similar reference numerals may describe similar components in different views. Similar reference numerals with different suffix letters may represent similar components in different examples. The drawings show generally, by way of example without limitation, various embodiments discussed herein.

FIG. 1 is a schematic diagram of a semiconductor structure according to an embodiment of the present disclosure;

FIG. 2 is a schematic diagram of a semiconductor structure according to an embodiment of the present disclosure;

FIG. 3 is a schematic diagram of a semiconductor structure according to an embodiment of the present disclosure;

FIG. 4 is a schematic flowchart of a method for forming a semiconductor structure according to an embodiment of the present disclosure;

FIG. 5 is a schematic structural diagram illustrating a process for forming a semiconductor structure according to an embodiment of the present disclosure;

FIG. 6 is a schematic structural diagram illustrating a process for forming a semiconductor structure according to an embodiment of the present disclosure;

FIG. 7 is a schematic structural diagram illustrating a process for forming a semiconductor structure according to an embodiment of the present disclosure;

FIG. 8 is a schematic structural diagram illustrating a process for forming a semiconductor structure according to an embodiment of the present disclosure;

FIG. 9 is a schematic structural diagram illustrating a process for forming a semiconductor structure according to an embodiment of the present disclosure;

FIG. 10 is a schematic structural diagram illustrating a process for forming a semiconductor structure according to an embodiment of the present disclosure;

FIG. 11 is a schematic structural diagram illustrating a process for forming a semiconductor structure according to an embodiment of the present disclosure;

FIG. 12 is a schematic structural diagram illustrating a process for forming a semiconductor structure according to an embodiment of the present disclosure;

FIG. 13 is a schematic structural diagram illustrating a process for forming a semiconductor structure according to an embodiment of the present disclosure;

FIG. 14 is a schematic structural diagram illustrating a process for forming a semiconductor structure according to an embodiment of the present disclosure;

FIG. 15 is a schematic structural diagram illustrating a process for forming a semiconductor structure according to an embodiment of the present disclosure;

FIG. 16 is a schematic structural diagram illustrating a process for forming a semiconductor structure according to an embodiment of the present disclosure;

FIG. 17 is a schematic structural diagram illustrating a process for forming a semiconductor structure according to an embodiment of the present disclosure;

FIG. 18 is a schematic structural diagram illustrating a process for forming a semiconductor structure according to an embodiment of the present disclosure;

FIG. 19 is a schematic structural diagram illustrating a process for forming a semiconductor structure according to an embodiment of the present disclosure; and

FIG. 20 is a schematic structural diagram illustrating a process for forming a semiconductor structure according to an embodiment of the present disclosure.

### DETAILED DESCRIPTION

Exemplary embodiments of the present disclosure will be described in more detail below with reference to the drawings. While exemplary embodiments of the present disclosure are shown in the drawings, it should be understood that the present disclosure may be implemented in various forms and should not be limited by the specific embodiments set forth herein. Rather, these embodiments are provided so that the present disclosure will be more thoroughly understood and the scope of the present disclosure will be fully conveyed to those skilled in the art.

In the following descriptions, many details are provided for a more thorough understanding of the present disclosure. However, it is apparent to those skilled in the art that the present disclosure can be implemented without one or more of these details. In other instances, some well-known technical features in the art are not described to avoid confusion with the present disclosure; i.e., not all features of the actual embodiments are described herein, and well-known functions and structures are not described in detail.

In the drawings, the dimensions of layers, regions, and elements, and their relative dimensions may be exaggerated for clarity. Identical reference numerals represent identical elements throughout the text.

It should be appreciated that when an element or a layer is referred to as being “on”, “adjacent to”, “connected to”, or “coupled to” another element or layer, it may be directly on, adjacent to, connected to, or coupled to the another element or layer, or an intervening element or layer may be present. On the contrary, when an element is referred to as being “directly on”, “directly adjacent to”, “directly connected to”, or “directly coupled to” another element or layer, no intervening element or layer is present. It should be appreciated that, although the terms first, second, third, etc., may be used to describe various elements, components, regions, layers, and/or parts, the elements, components, regions, layers, and/or parts should not be limited by these terms. These terms are only used to distinguish one element, component, region, layer, or part from another element, component, region, layer, or part. Therefore, a first element, component, region, layer, or part discussed below may be termed a second element, component, region, layer, or part without departing from the teachings of the present disclosure. However, the discussion of a second element, component, region, layer, or part does not necessarily imply that a first element, component, region, layer, or part is necessarily present in the present disclosure.

The terms used herein are for the purpose of describing specific embodiments only and should not be construed as limiting the present disclosure. As used herein, the singular forms “a”, “an”, and “the” are intended to include the plural forms as well, unless the context clearly indicates otherwise. It should be further appreciated that the terms “comprise” and/or “include” when used in this specification, specify the presence of stated features, integers, steps, operations, elements, and/or components, but do not preclude the presence or addition of one or more other features, integers, steps, operations, elements, components, and/or groups. As used herein, the term “and/or” includes any and all combinations of the associated listed items.

Currently, a hexagonal arrangement using six times the square of the feature size (6F²) and buried word lines are often adopted to manufacture small-sized Dynamic Random Access Memory (Dynamic Random Access Memory, DRAM). However, when further miniaturizing such small-sized DRAM, its electrical performance may be severely compromised, making the miniaturization of DRAM extremely challenging. To achieve the miniaturization of semiconductor structure sizes, a CAA structure is typically used as the channel structure for IGZO transistors. However, in the CAA structures based on IGZO devices, the gate structure is relatively close to the source/drain, which makes it easy for GIDL to occur between the gate structure and the source/drain.

Based on this, the embodiments of the present disclosure provide a semiconductor structure. The semiconductor structure includes: a substrate; word line structures located on the substrate and spaced apart along a first direction, each word line structure including a plurality of gate structures spaced apart sequentially along a third direction; a plurality of active pillar structures, disposed on the outer wall of each gate structure, where at least one end of each active pillar structure along a second direction is provided with a trench with an opening facing the second direction; the part of the active pillar structure surrounding the gate structure constitutes a channel structure, and the part of the active pillar structure, located on both sides of the channel structure along the second direction and adjacent to the trench, constitutes the source/drain; and an isolation structure, located on the inner wall of the trench adjacent to the gate structure. Because at least one end of the active pillar structure along the second direction is provided with a trench with an opening facing the second direction, and the part of the active pillar structure adjacent to the trench constitutes the source/drain, such an arrangement can not only increase the distance between the gate structure and the drain, reducing the generation of GIDL, but also increase the contact area between the capacitor structure and the source/drain as well as between the bit line and the source/drain. This can reduce contact resistance and improve the response speed of the semiconductor structure. In addition, because the inner wall of the trench adjacent to the gate structure is provided with an isolation structure, such an arrangement can not only further reduce GIDL but also reduce the parasitic capacitance between the gate structure and the capacitor structure and between the gate structure and the bit line, thereby reducing the power consumption of the semiconductor structure.

A semiconductor structure and a method for forming the same in the embodiments of the present disclosure are described in detail below with reference to the drawings.

Before describing the embodiments of the present disclosure, three directions for describing a three-dimensional structure that may be used in the following embodiments are defined. Taking the Cartesian coordinate system as an example, the three directions may include the X-axis, Y-axis, and Z-axis directions. A substrate may include a top surface at the front side and a bottom surface at the back side opposite the front side. A direction intersecting (for example, perpendicular to) the top surface and bottom surface of the substrate is defined as a third direction, without considering the flatness of the top surface and bottom surface. In the direction of the top surface and the bottom surface of the substrate (namely, a plane where the base substrate is located), two intersecting directions (for example, perpendicular to each other) are defined. For example, the direction in which the word line structures are arranged may be defined as the first direction. Based on the first direction and the second direction, the planar direction of the substrate can be determined. In the embodiments of the present disclosure, the first direction, the second direction, and the third direction may be perpendicular to one another. In other embodiments, the first direction, the second direction, and the third direction may not be perpendicular to one another. In the embodiments of the present disclosure, the first direction is defined as the X-axis direction, the second direction is defined as the Y-axis direction, and the third direction is defined as the Z-axis direction.

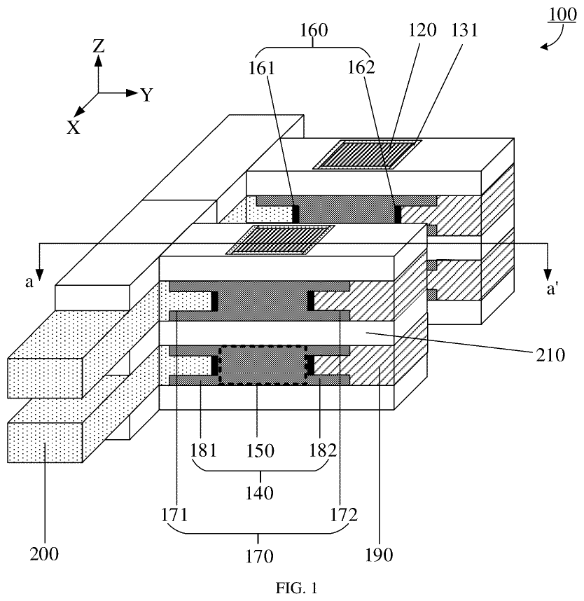

FIGS. 1 to 3 are schematic structural diagrams of a semiconductor structure 100 according to an embodiment of the present disclosure. As shown in FIGS. 1 to 3, the semiconductor structure 100 includes: a substrate 110; word line structures 120 spaced apart along the X-axis direction on the substrate 110, each word line structure 120 including a plurality of a gate structures 130 spaced apart sequentially along the Z-axis direction; a plurality of active pillar structures 140, disposed on the outer wall of each gate structure 130, where at least one end of the active pillar structure 140 along the Y-axis direction is provided with a trench 170 with an opening facing the Y-axis direction; the part of the active pillar structure 140 surrounding the gate structure 130 constitutes a channel structure 150, and the part of the active pillar structure 140 located on both sides of the channel structure 150 along the Y-axis direction and adjacent to the trench constitutes the source/drain (i.e., 181 and 182 in the figure); and an isolation structure 160, located on the inner wall of the trench adjacent to the gate structure 130.

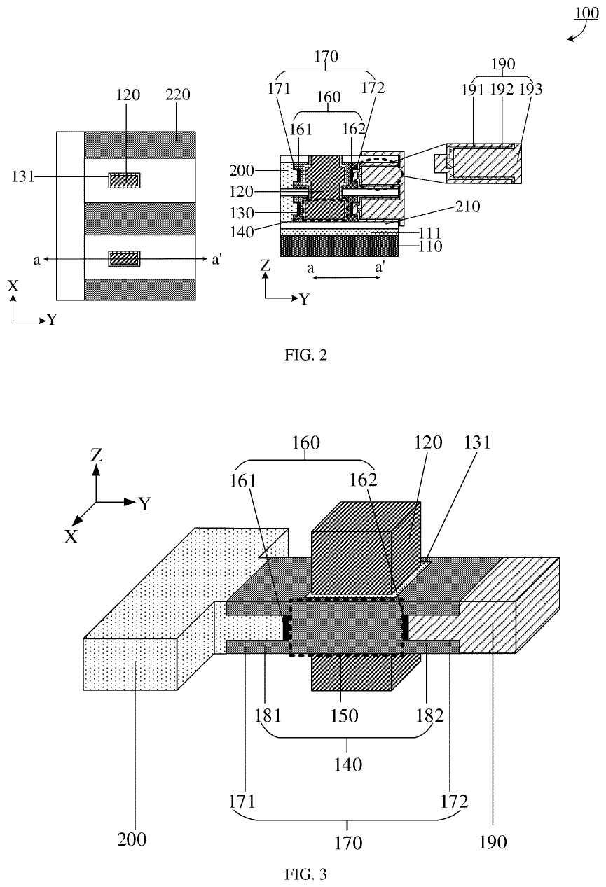

It should be noted that FIG. 2 provides a top view and a cross-sectional view along the line a-a′ of the semiconductor structure 100 in FIG. 1 according to the embodiment of the present disclosure, and FIG. 3 is a schematic structural diagram of a memory cell within the semiconductor structure 100. In addition, the substrate 110 and the gate structure 130 are not shown in FIG. 1. For the position of the substrate 110 and the gate structure 130, please refer to FIG. 2 for understanding.

In the embodiment of the present disclosure, the substrate 110 may be a silicon substrate, a germanium substrate, a silicon-germanium substrate, a Silicon On Insulator (Silicon On Insulator, SOI) substrate, a Germanium-On-Insulator (Germanium-On-Insulator, GOI) substrate, or the like. The substrate 110 may further include other elemental semiconductors or compound semiconductors, such as gallium arsenide, indium phosphide, or silicon carbide. In other embodiments, the substrate 110 may also be a substrate that has undergone ion doping, such as a P-type doped substrate or an N-type doped substrate.

With further reference to FIGS. 1 to 3, the word line structure 120 extends along the Z-axis direction. In this way, on the one hand, the distance between memory cells arranged along the Z-axis direction can be reduced, thereby effectively reducing signal delay and improving signal transmission speed; on the other hand, the integration level of the stacked structure of the semiconductor structure 100 can be enhanced, thereby increasing the memory density of the semiconductor structure 100. In this way, the space within the semiconductor structure can be effectively utilized, achieving miniaturization of the semiconductor structure.

With further reference to FIGS. 1 to 3, the word line structure 120 may be provided with at least one gate structure 130 (i.e., a protruding part on the word line structure 120) and at least one recessed part. The gate structures 130 and the recessed parts are alternately arranged sequentially along the Z-axis direction. The dimension of the gate structure 130 along the Y-axis direction is greater than that of the recessed part along the Y-axis direction, and the dimension of the gate structure 130 along the X-axis direction is greater than that of the recessed part along the X-axis direction. In this way, the contact area between the gate structure 130 and the channel structure (i.e., the active pillar structure 140) can be increased, thereby enhancing the control capability of the gate structure 130.

In the embodiment of the present disclosure, the gate structure 130 can be axisymmetric along the Z-axis (please refer to FIG. 2) or mirror-symmetric along the XZ plane. In this way, the gate structure 130 can uniformly control the channel structure, leading to more stable and uniform signal transmission.

In the embodiment of the present disclosure, with further reference to FIGS. 1 to 3, each word line structure 120 includes a plurality of gate structures 130 spaced apart sequentially along the Z-axis direction. The gate structure 130 includes a gate insulating layer 131 and a gate conductive layer. The material of the word line structure 120 may be any of cobalt (Co), titanium (Ti), tantalum (Ta), nickel (Ni), tungsten (W), platinum (Pt), or palladium (Pd). The gate insulating layer 131 may be made of high-k (HK) materials or other suitable materials such as silicon oxide. The high-k materials may include, for example, hafnium oxide (HfO₂), hafnium silicon oxide (HfSiO₂), zirconium oxide (ZrO₂), and aluminum oxide (Al₂O₃).

In the embodiment of the present disclosure, with further reference to FIGS. 1 to 3, the plurality of active pillar structures 140 being disposed on the outer wall of each gate structure 130 means that: Each active pillar structure 140 is arranged around the outer side of the corresponding gate structure 130. In other words, each word line structure 120 penetrates through a plurality of active pillar structures 140 arranged along the Z-axis direction.

In the embodiment of the present disclosure, both ends of the active pillar structure 140 along the Y-axis direction are provided with a trench with an opening facing the Y-axis direction (please refer to FIGS. 1 to 3), that is, two trenches are provided. Alternatively, either end of the active pillar structure 140 along the Y-axis direction is provided with a trench with an opening facing the Y-axis direction, that is, one trench is provided. Here, the number of trenches on the active pillar structure 140 can be set according to actual needs.

It should be noted that the transistor of the semiconductor structure 100 is an oxide thin-film transistor. Understandably, the material of the active pillar structure 140 (i.e., channel structure 150) may include oxide semiconductors, such as indium gallium zinc oxide. Due to the inherent characteristics of oxide semiconductors (lower electron mobility), when the material of the active pillar structure 140 uses oxide semiconductors, the leakage current of the transistor on the surface of the active pillar structure 140 can be reduced. This reduction in leakage current can lead to a slower charge loss speed on the capacitor structure 190, thereby extending the data retention time of the semiconductor structure 100 and reducing the power consumption of the semiconductor structure. In other embodiments, the transistors of the semiconductor structure 100 may also be ordinary silicon-based transistors or other types of transistors.

In the embodiment of the present disclosure, because at least one end of the active pillar structure along the Y-axis direction is provided with a trench with an opening facing the Y-axis direction, and the part of the active pillar structure adjacent to the trench constitutes the source/drain, such an arrangement can not only increase the distance between the gate structure and the drain, reducing the generation of GIDL, but also increase the contact area between the capacitor structure and the source/drain as well as between the bit line and the source/drain. This can reduce contact resistance and improve the response speed of the semiconductor structure. In addition, because the inner wall of the trench adjacent to the gate structure is provided with an isolation structure, such an arrangement can not only further reduce GIDL but also reduce the parasitic capacitance between the gate structure and the capacitor structure and between the gate structure and the bit line, thereby reducing the power consumption of the semiconductor structure.

In some embodiments, with further reference to FIGS. 1 to 3, the trench 170 includes a first trench 171 and a second trench 172 located respectively at both ends of the active pillar structure 140 along the Y-axis direction. The isolation structure 160 includes a first isolation structure 161 and a second isolation structure 162; the first isolation structure 161 is located on the inner wall of the first trench 171 adjacent to the gate structure 130, and the second isolation structure 162 is located on the inner wall of the second trench 172 adjacent to the gate structure 130.

In the embodiment of the present disclosure, the first isolation structure 161 and the second isolation structure 162 may be made of any insulating material, such as silicon oxide or silicon oxynitride. The first isolation structure 161 and the second isolation structure 162 may also be an air gap. Due to the relatively low dielectric constant of air, setting the first isolation structure 161 and the second isolation structure 162 as air gaps can reduce the parasitic capacitance of structures (e.g., bit line 200 and capacitor structure 190) that are in contact with the channel structure 150, thereby improving the read/write performance of the semiconductor structure.

Here, the materials of the first isolation structure 161 and the second isolation structure 162 may be the same or different. For example, the materials of both the first isolation structure 161 and the second isolation structure 162 may be silicon oxide; for another example, the material of the first isolation structure 161 may be silicon oxynitride, and the second isolation structure 162 may be an air gap. The thickness of the first isolation structure 161 and the second isolation structure 162 is greater than that of the gate insulating layer 131.

In the embodiment of the present disclosure, since the first isolation structure 161 is located on the inner wall of the first trench 171 adjacent to the gate structure 130, and the second isolation structure 162 is located on the inner wall of the second trench 172 adjacent to the gate structure 130, this arrangement can not only further reduce GIDL but also reduce the parasitic capacitance between the gate structure and the capacitor structure and between the gate structure and the bit line, thereby reducing the power consumption of the semiconductor structure.

In some embodiments, with further reference to FIG. 2, the side wall of the word line structure 120 in cross-section along the Z-axis direction is serrated. That is, the side wall of the gate structure 130 in cross-section along the Z-axis direction is serrated. In this way, the contact area between the gate structure 130 and the channel structure (i.e., the active pillar structure 140) can be increased, thereby enhancing the control capability of the gate structure 130.

In some embodiments, with further reference to FIGS. 1 to 3, the source/drain includes a first source/drain 181 and a second source/drain 182 which are located at both ends of the active pillar structure 140 along the Y-axis direction. The part of the active pillar structure 140 adjacent to the first trench 171 constitutes the first source/drain 181, and the part of the active pillar structure 140 adjacent to the second trench 172 constitutes the second source/drain 182.

In the embodiment of the present disclosure, the first source/drain 181 and the second source/drain 182 may be doped with atoms, ions, or plasma of Group III elements such as boron, gallium, and indium; the first source/drain and the second source/drain may also be doped with atoms, ions, or plasma of Group V elements such as phosphorus, antimony, and arsenic, which is not limited in the embodiments of the present disclosure.

In the embodiment of the present disclosure, because at least one end of the active pillar structure along the Y-axis direction is provided with a first trench 171 and a second trench 172 with an opening facing the Y-axis direction, and the part of the active pillar structure 140 adjacent to the first trench 171 constitutes the first source/drain 181, while the part of the active pillar structure 140 adjacent to the second trench 172 constitutes the second source/drain 182, such an arrangement can not only increase the distance between the gate structure and the drain, reducing the generation of GIDL, but also increase the contact area between the capacitor structure and the second source/drain 182, as well as the contact area between the bit line and the first source/drain 181, thereby reducing contact resistance and improving the response speed of the semiconductor structure.

In some embodiments, with further reference to FIGS. 1 to 3, the semiconductor structure 100 further includes: a bit line 200 and a capacitor structure 190. The bit line 200 is connected to the first source/drain 181 and is embedded in the first trench 171, contacting the first isolation structure 161; the capacitor structure 190 is connected to the second source/drain 182 and is embedded in the second trench 172, contacting the second isolation structure 162.

In the embodiment of the present disclosure, with further reference to FIG. 2, the capacitor structure 190 includes a first electrode layer 191, a dielectric layer 192, and a second electrode layer 193. The material of the first electrode layer 191 and the second electrode layer 193 may include metal nitrides or metal silicides, such as titanium nitride. The material of the dielectric layer 192 may include high-K dielectric materials, which, for example, may be one or any combination of lanthanum oxide (La₂O₃), aluminum oxide, hafnium oxide, hafnium oxynitride (HfON), hafnium silicate (HfSiOₓ), or zirconium oxide, either individually or in any combination. In other embodiments, the material of the first electrode layer 191 and the second electrode layer 193 may also be polysilicon.

In the embodiment of the present disclosure, the capacitor structure 190 is in a horizontal form and is arranged in an array along the X-axis and Z-axis directions. The horizontal configuration of the capacitor structure 190 can reduce the likelihood of toppling or breaking. A plurality of capacitor structures 190 stacked in the Z-axis direction form a stacked structure, which can form a three-dimensional semiconductor structure, thereby increasing the integration level of the semiconductor structure 100 and achieving miniaturization.

In the embodiment of the present disclosure, the material of the bit line 200 includes tungsten, cobalt, copper (Cu), aluminum (Al), titanium nitride (TiN), polysilicon, or any combination thereof.

In some embodiments, with further reference to FIGS. 1 to 3, the bit line 200 extends along the X-axis direction, and a row of bit lines 200 arranged along the X-axis direction are interconnected. A plurality of bit lines 200 arranged along the Z-axis direction form a staircase structure.

In some embodiments, with further reference to FIGS. 1 to 3, the semiconductor structure 100 further includes: a spacer layer 210. The spacer layer 210 is located between a plurality of bit lines 200 arranged along the Z-axis direction, between a plurality of capacitor structures 190 arranged along the Z-axis direction, and between a plurality of active pillar structures 140 arranged along the Z-axis direction.

In the embodiment of the present disclosure, the material of the spacer layer 210 may be silicon nitride or silicon carbonitride. On the one hand, the spacer layer 210 may be configured to support the formed capacitor structure, reducing the collapse of the capacitor structure and improving the stability of the formed semiconductor structure; on the other hand, the spacer layer 210 may also isolate adjacent capacitor structures, as well as the capacitor structure from the bit line structure, reducing the generation of leakage current.

It should be noted that, with further reference to FIG. 2, the spacer layer 210 is also located between the substrate 110 and the memory cell.

In the embodiment of the present disclosure, with further reference to FIG. 2, the semiconductor structure 100 further includes a second insulating structure 111. The second insulating structure 111 is located between the substrate 110 and the spacer layer 210. The material of the second insulating structure 111 may be any insulating material, such as silicon oxide. The second insulating structure 111 and the spacer layer 210 are both configured to isolate the memory cell and the substrate 110, thus reducing leakage from the memory cell and improving the performance of the semiconductor structure.

In the embodiment of the present disclosure, with further reference to FIG. 2, the semiconductor structure 100 also includes a first insulating structure 220. The first insulating structure 220 is located between adjacent memory cells along the X-axis direction to prevent leakage from the memory cells. In addition, a low-k (low dielectric constant) material may be used as the material of the first insulating structure 220. In this way, the parasitic capacitance of the semiconductor structure can be reduced, thereby decreasing the capacitance-resistance delay and improving the response time of the semiconductor structure.

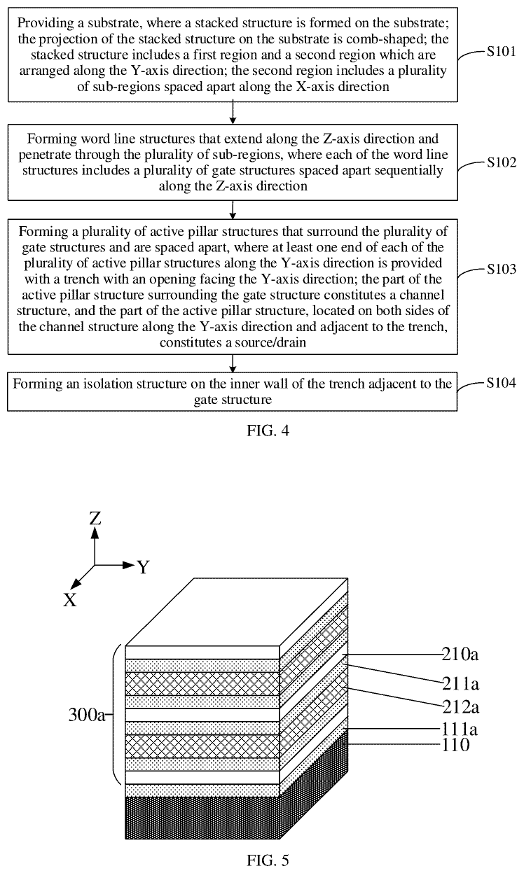

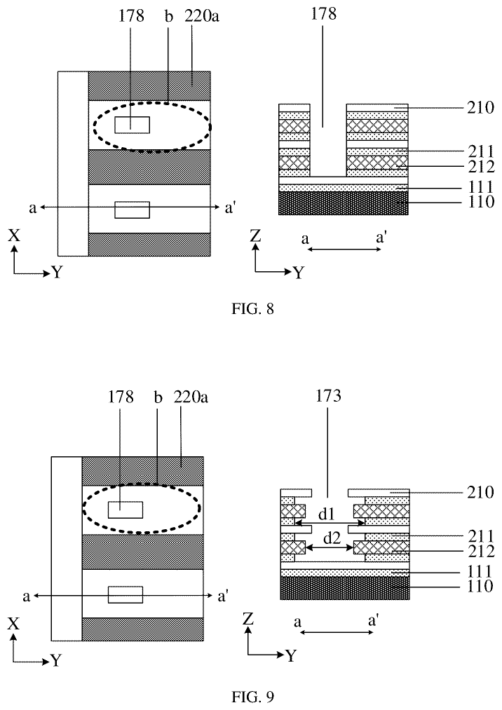

Moreover, the embodiments of the present disclosure further provide a method for forming a semiconductor structure. FIG. 4 is a schematic flowchart of a method for forming a semiconductor structure according to an embodiment of the present disclosure, and FIGS. 5 to 20 are schematic structural diagrams illustrating a process for forming a semiconductor structure according to an embodiment of the present disclosure. Among the figures, FIGS. 5 to 7 are three-dimensional views; FIGS. 8 to 20 are top views illustrating the process for forming the semiconductor structure, as well as cross-sectional views along a-a′ and b-b′. As shown in FIG. 4, the method for forming a semiconductor structure includes steps S101 to S104.

First, referring to FIGS. 4 to 7, step S101 is performed to provide a substrate 110. A stacked structure 300 is formed on the substrate 110. The projection of the stacked structure 300 on the substrate 110 is comb-shaped. The stacked structure 300 includes a first region A and a second region B which are arranged along the Y-axis direction; the second region B includes a plurality of sub-regions b spaced apart along the X-axis direction.

In some embodiments, the stacked structure 300 can be formed by the following steps S1011 and S1012:

In step S1011, an initial spacer layer 210a, an initial first sacrificial layer 211a, an initial second sacrificial layer 212a, and an initial first sacrificial layer 211a are alternately and cyclically stacked on a surface of the substrate 110, thereby forming an initial stacked structure 300a as shown in FIG. 5.

Here, with further reference to FIG. 5, before the initial stacked structure 300a is formed, the method for forming a semiconductor structure 100 further includes: forming an initial second insulating structure 111a located between the initial spacer layer 210a and the substrate 110.

During implementation, a second insulating material can be sequentially deposited on the surface of the substrate 110 to form the initial second insulating structure 111a as shown in FIG. 5. A spacer material, a first sacrificial material, and a second sacrificial material are sequentially and cyclically deposited on the surface of the initial second insulating structure 111a, thereby forming an initial spacer layer 210a, an initial first sacrificial layer 211a, an initial second sacrificial layer 212a, and an initial first sacrificial layer 211a that are alternately and cyclically stacked as shown in FIG. 5.

In the embodiment of the present disclosure, the number of layers of the initial spacer layer 210a, the initial first sacrificial layer 211a, and the initial second sacrificial layer 212a in the initial stacked structure 300a may be set according to the required capacitance density (or storage density). The greater the number of layers of the initial spacer layer 210a, the initial first sacrificial layer 211a, and the initial second sacrificial layer 212a is, the higher the integration level of the formed semiconductor structure 100 is and the greater the density of the capacitor structure 190 is. During implementation, the initial spacer layer 210a may consist of three layers, the initial first sacrificial layer 211a may consist of five layers, and the initial second sacrificial layer 212a may consist of two layers.

In the embodiment of the present disclosure, the second insulating material may be any insulating material, such as silicon oxide; the spacer material may be silicon nitride or silicon carbonitride. The first sacrificial material may be, for example, silicon oxide, and the second sacrificial material may be, for example, polysilicon, such that the first sacrificial material is more easily removed than the second sacrificial material under the same etching conditions.

In the embodiment of the present disclosure, the initial second insulating structure 111a, the initial spacer layer 210a, the initial first sacrificial layer 211a, and the initial second sacrificial layer 212a may be formed by any of the following deposition processes: a Chemical Vapor Deposition (Chemical Vapor Deposition, CVD) process, a Physical Vapor Deposition (Physical Vapor Deposition, PVD) process, an Atomic Layer Deposition (Atomic Layer Deposition, ALD) process, or other suitable processes.

In step S1012, the initial stacked structure 300a is etched to form the stacked structure 300.

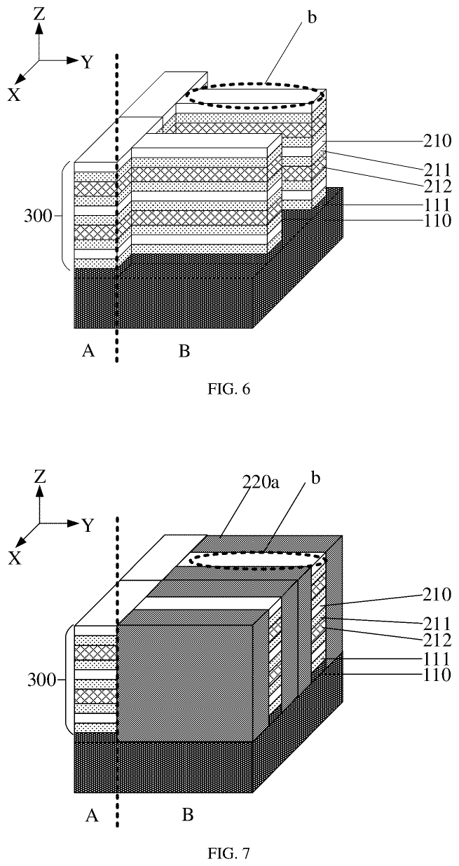

During implementation, the initial stacked structure 300a may be etched, for example, by a dry etching process or a wet etching process, to form the stacked structure 300 as shown in FIG. 6. The stacked structure 300 includes a spacer layer 210, a first sacrificial layer 211, a second sacrificial layer 212, and a first sacrificial layer 211 that are alternately and cyclically arranged along the Z-axis direction.

It should be noted that, with further reference to FIG. 6, while the initial stacked structure 300a is etched, the initial second insulating structure 111a is also etched to form a second insulating structure 111. Moreover, part of the substrate 110 is etched.

In the embodiment of the present disclosure, after step S101 is performed, the method for forming the semiconductor structure 100 further includes: depositing a first insulating material between the sub-regions b to form an initial first insulating structure 220a as shown in FIG. 7. The first insulating material may be a low-k dielectric material. The initial first insulating structure 220a can protect the side surface of the stacked structure 300 along the X-axis direction from being damaged when the stacked structure 300 is subsequently processed.

Next, referring to FIG. 4 and FIGS. 8 to 13, step S102 is performed to form a word line structure 120 extending along the Z-axis direction and penetrating through the sub-region b. Each word line structure 120 includes a plurality of gate structures 130 spaced apart sequentially along the Z-axis direction.

In some embodiments, the word line structure 120 extending along the Z-axis direction and penetrating through the sub-region b can be formed by the following steps S1021 to S1023:

In step S1021, the sub-region b is etched to form a third trench 173 extending along the Z-axis direction. The third trench 173 exposes the spacer layer 210 at the lowest level.

In some embodiments, step S1021 can be formed by the following steps:

In step S1021a, the sub-region b is etched until the spacer layer 210 at the lowest level is exposed, thereby forming an eighth trench 178 extending along the Z-axis direction.

During implementation, the sub-region b may be etched by a wet etching process (for example, etching with strong acids such as concentrated sulfuric acid, hydrofluoric acid, and concentrated nitric acid) or a dry etching process (for example, a plasma etching process, a reactive ion etching process, or an ion beam milling process) until the spacer layer 210 at the lowest level is exposed, thereby forming the eighth trench 178 extending along the Z-axis direction as shown in FIG. 8.

In step S1021b, through the eighth trench 178, lateral etching is performed to remove part of the first sacrificial layer 211 and part of the second sacrificial layer 212, thereby forming a third trench 173. The third trench 173 encloses the eighth trench 178 and is serrated. The dimension d1 of the third trench 173 between the first sacrificial layers 211 is greater than the dimension d2 of the third trench 173 between the second sacrificial layer 212.

During implementation, a wet etching process may be adopted to laterally etch through the eighth trench 178. The lateral etching removes part of the first sacrificial layer 211 and part of the second sacrificial layer 212, thereby forming the third trench 173 as shown in FIG. 9. An etching solution may be hydrofluoric acid (DHF), a mixed solution of diluted hydrofluoric acid and ammonia (NH₄OH), or a mixed solution of diluted hydrofluoric acid and tetramethylammonium hydroxide (TMAH).

It should be noted that, due to the larger etching selectivity of the first sacrificial layer 211 relative to the second sacrificial layer 212, the first sacrificial layer 211 is more easily etched and removed compared to the second sacrificial layer 212 during the etching process. Therefore, when the third trench 173 is formed, the dimension of the third trench 173 between the first sacrificial layers 211 is greater than the dimension of the third trench 173 between the second sacrificial layers 212. In addition, the dimension d1 of the third trench 173 between the first sacrificial layers 211 and the dimension d2 of the third trench 173 between the second sacrificial layers 212 may both be a dimension or an area in any direction in the substrate plane.

In step S1022, a first initial active pillar structure 140a is formed on part of the inner wall of the third trench 173.

In some embodiments, step S1022 can be formed by the following steps:

In step S1022a, a second initial active pillar structure 140b is formed on the inner wall as well as at the bottom of the third trench 173.

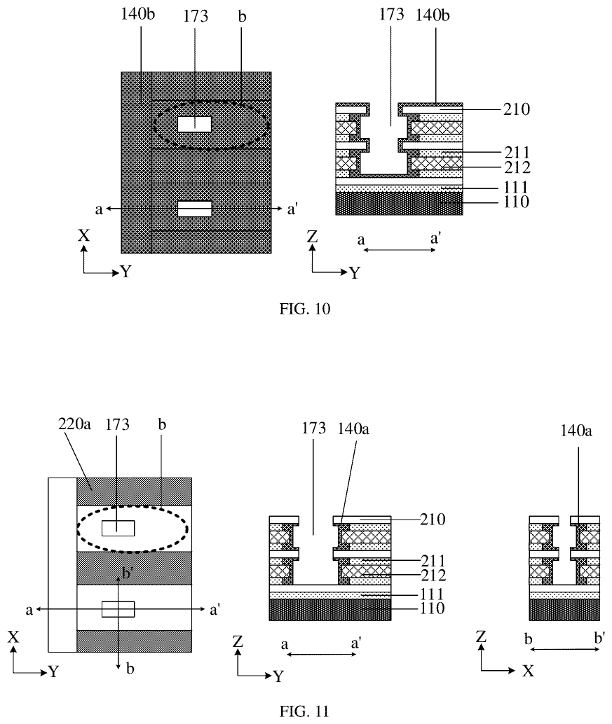

During implementation, an active material may be deposited on the inner wall as well as at the bottom of the third trench 173 to form the second initial active pillar structure 140b as shown in FIG. 10. The active material may include an oxide semiconductor, such as indium gallium zinc oxide. The second initial active pillar structure 140b may be formed by any of the following deposition processes: a chemical vapor deposition process, a physical vapor deposition process, an atomic layer deposition process, or other suitable processes.

In step S1022b, the second initial active pillar structure 140b at the bottom of the third trench 173 and on the side wall of the spacer layer 210 is removed to form the first initial active pillar structure 140a.

During implementation, the second initial active pillar structure 140b may be etched by a dry etching process or a wet etching process to remove the second initial active pillar structure 140b at the bottom of the third trench 173, on the side wall of the spacer layer 210, and on the surface of the topmost spacer layer 210, thereby forming the first initial active pillar structure 140a as shown in FIG. 11.

In step S1023, the first initial active pillar structure 140a is partially or fully embedded in the first sacrificial layer 211. The word line structure 120 is formed in the third trench 173 provided with the first initial active pillar structure 140a.

It should be noted that if the first initial active pillar structure 140a is fully embedded in the first sacrificial layer 211, the first trench 171 and the second trench 172 can be subsequently formed at the same time. In other embodiments, if the first initial active pillar structure 140a is partially embedded in the first sacrificial layer 211, only the first trench 171 or the second trench 172 is subsequently formed. In the embodiment of the present disclosure, the explanation is provided using the example where the first initial active pillar structure 140a is fully embedded in the first sacrificial layer 211.

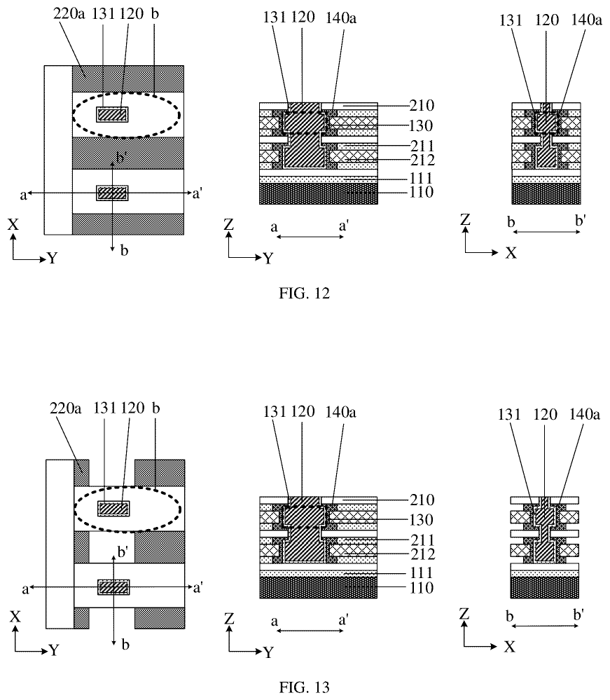

During implementation, after the first initial active pillar structure 140a is formed, a gate insulating material and a conductive material are sequentially deposited in the third trench 173 provided with the first initial active pillar structure 140a, thereby forming a gate insulating layer 131 and a gate conductive layer as shown in FIG. 12. The gate insulating layer 131 and the gate conductive layer constitute a gate structure 130. The gate conductive layer may serve as the word line structure 120 as shown in FIG. 12.

Here, the gate insulating material may be a high-k (HK) material or other suitable materials such as silicon oxide. The high-k material may include, for example, hafnium oxide (HfO₂), hafnium silicon oxide (HfSiO₂), zirconium oxide (ZrO₂), and aluminum oxide (Al₂O₃). The conductive material may be any of cobalt (Co), titanium (Ti), tantalum (Ta), nickel (Ni), tungsten (W), platinum (Pt), and palladium (Pd). The gate insulating layer 131 and the word line structure 120 may be formed through any suitable process.

Referring to FIG. 13, after the word line structure 120 is formed, the method for forming the semiconductor structure 100 further includes: removing part of the initial first insulating structure 220a to expose part of the first sacrificial layer 211. Specifically, part of the initial first insulating structure 220a may be removed by a dry etching process or a wet etching process, to expose both sides of the first sacrificial layer 211 along the X-axis direction.

With further reference to FIG. 13, after both sides of the first sacrificial layer 211 along the X-axis direction are exposed, part of the first sacrificial layer 211 is removed along the X-axis direction by a lateral etching method to expose both sides of the first initial active pillar structure 140a along the X-axis direction.

Next, referring to FIG. 4 and FIGS. 14 and 15, step S103 is performed to form a plurality of active pillar structures 140 which surround the gate structure 130 and are spaced apart. At least one end of the active pillar structure 140 along the Y-axis direction is provided with a trench 170 with an opening facing the Y-axis direction. The part of the active pillar structure 140 surrounding the gate structure 130 constitutes a channel structure 150, and the part of the active pillar structure 140, located on both sides of the channel structure 150 along the Y-axis direction and adjacent to the trench 170, constitutes a source/drain.

In some embodiments, in step S103, forming the plurality of active pillar structures 140 which surround the gate structure 130 and are spaced apart includes:

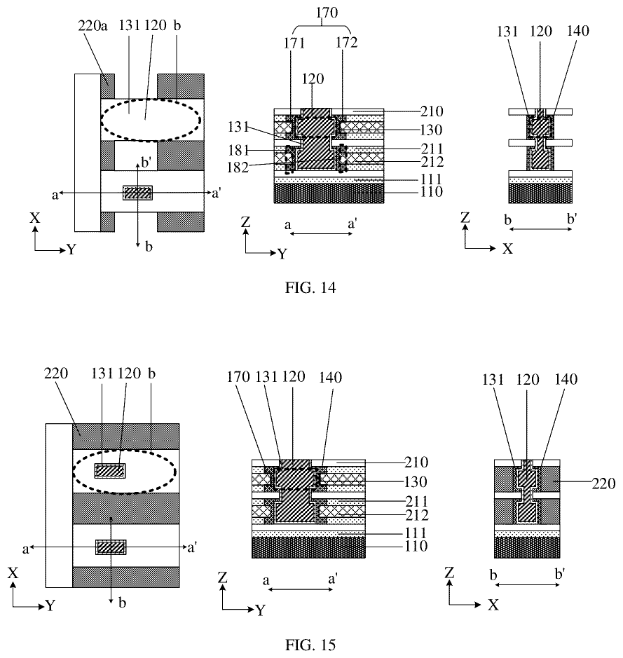

The part of the first initial active pillar structure 140a that extends along the X-axis direction into the space between the second sacrificial layer 212 and the spacer layer 210 is removed to form the active pillar structure 140 as shown in FIG. 14. The remaining part of the first initial active pillar structure 140a embedded between the second sacrificial layer 212 and the spacer layer 210 constitutes a source/drain; the region between the remaining part of the first initial active pillar structure 140a that extends into the space between the second sacrificial layer 212 and the spacer layer 210, and the first initial active pillar structure 140a located on the side wall of the second sacrificial layer 212, forms the trench 170.

Here, with further reference to FIG. 14, the trench 170 includes a first trench 171 and a second trench 172 located respectively at two ends of the active pillar structure 140 along the Y-axis direction. The source/drain includes a first source/drain 181 and a second source/drain 182 which are located at both ends of the active pillar structure 140 along the Y-axis direction. The part of the active pillar structure 140 adjacent to the first trench 171 constitutes the first source/drain 181, and the part of the active pillar structure 140 adjacent to the second trench 172 constitutes the second source/drain 182.

During implementation, a lateral etching method may be performed to remove the part of the first initial active pillar structure 140a that extends along the X-axis direction into the space between the second sacrificial layer 212 and the spacer layer 210 to form the active pillar structure 140 as shown in FIG. 14.

In the embodiment of the present disclosure, with further reference to FIG. 14, after the active pillar structure 140 is formed, the method for forming the semiconductor structure 100 further includes: removing the second sacrificial layer 212 exposed in the X-axis direction and exposing both sides of the active pillar structure 140 along the X-axis direction.

In the embodiment of the present disclosure, after the second sacrificial layer 212 exposed in the X-axis direction is removed, a first insulating material is deposited between two adjacent sub-regions b along the X-axis direction to form a first insulating structure 220 as shown in FIG. 15.

Finally, referring to FIG. 4 and FIGS. 16 to 20, step S104 is performed to form an isolation structure 160 on the inner wall of the trench adjacent to the gate structure 130.

In some embodiments, the isolation structure 160 includes a first isolation structure 161 located on the inner wall of the first trench 171 adjacent to the gate structure 130, as well as a second isolation structure 162 located on the inner wall of the second trench 172 adjacent to the gate structure 130. Step S104 may be formed by the following steps S1041 to S1042:

In step S1041, the second sacrificial layer 212 between the channel structures 150 is removed to form the first trench 171 and the second trench 172.

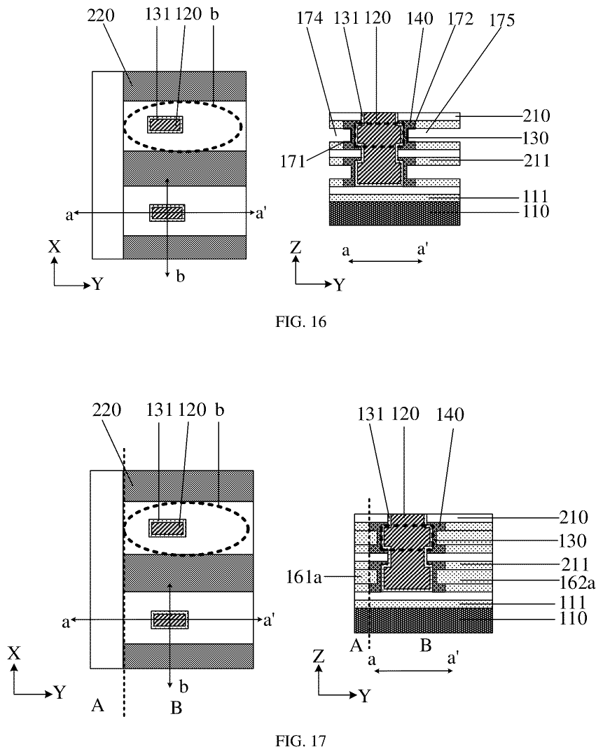

In some embodiments, the method for forming the semiconductor structure 100 further includes: removing the second sacrificial layer 212 in the stacked structure 300 while forming the first trench 171 and the second trench 172, to form a fourth trench 174 and a fifth trench 175 as shown in FIG. 16. The fourth trench 174 encloses the first trench 171, and the fifth trench 175 encloses the second trench 172.

During implementation, the second sacrificial layer 212 may be removed by adopting a wet etching process with a lateral etching method, thereby forming the fourth trench 174 and the fifth trench 175 as shown in FIG. 16.

In step S1042, a first isolation structure 161 and a second isolation structure 162 are formed respectively on the inner walls of the first trench 171 and the second trench 172 adjacent to the gate structure 130.

In some embodiments, step S1042 may be formed by the following steps:

In step S1042a, after the fourth trench 174 and the fifth trench 175 are formed, any insulating material is filled in the fourth trench 174 and the fifth trench 175 to form the initial first isolation structure 161a and the initial second isolation structure 162a as shown in FIG. 17. Here, the insulating material filled in the fourth trench 174 and the insulating material filled in the fifth trench 175 may be the same or different.

In step S1042b, the initial first isolation structure 161a is etched to form a first isolation structure 161.

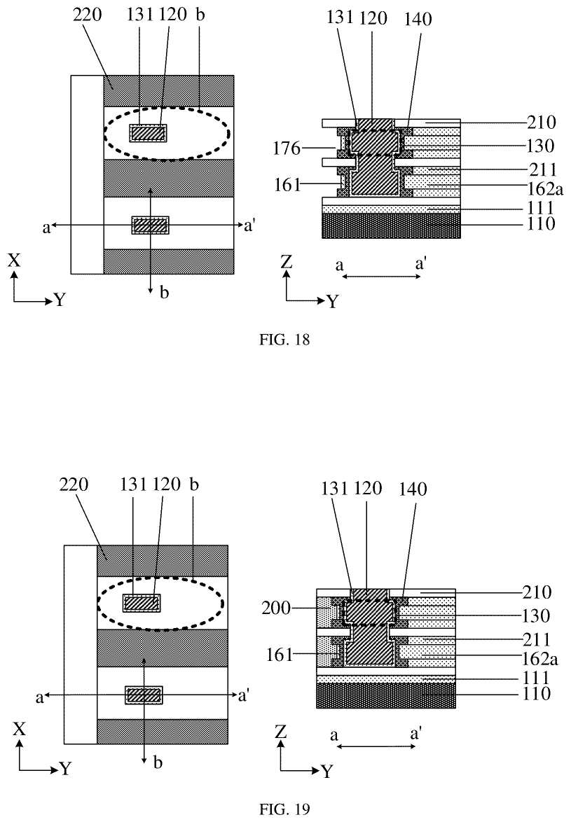

During implementation, the initial first isolation structure 161a may be etched by adopting a wet etching process with a lateral etching method, thereby forming the first isolation structure 161 as shown in FIG. 18.

Here, while or after forming the first isolation structure 161 shown in FIG. 18, the first sacrificial layer 211 on one side close to the first region A along the X-axis direction in the first region A and the second region B is removed, to form a sixth trench 176 as shown in FIG. 18. The sixth trench 176 encloses the fourth trench 174. A bit line 200 in contact with the first source/drain 181 is formed in the sixth trench 176 as shown in FIG. 19.

The bit line 200 extends along the X-axis direction, and a row of bit lines 200 arranged along the X-axis direction are interconnected. A plurality of bit lines 200 arranged along the Z-axis direction form a staircase structure.

In step S1042c, the initial second isolation structure 162a is etched to form a second isolation structure 162.

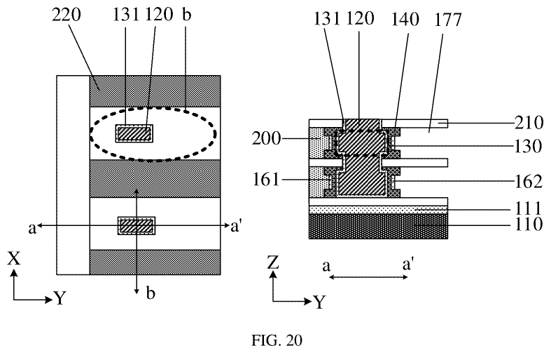

During implementation, the initial first isolation structure 162a may be etched by adopting a wet etching process with a lateral etching method, thereby forming the second isolation structure 162 as shown in FIG. 20.

Here, after or while forming the second isolation structure 162 shown in FIG. 20, the remaining first sacrificial layer 211 in the stacked structure 300 is removed to form a seventh trench 177 as shown in FIG. 20. The seventh trench 177 encloses the fifth trench 175. A capacitor structure 190 (referring to FIG. 2) in contact with the second source/drain 182 is formed in the seventh trench 177.

During implementation, the remaining first sacrificial layer 211 in the stacked structure 300 is removed to form a seventh trench 177. Next, a first electrode layer 191, a dielectric layer 192, and a second electrode layer 193 are sequentially formed in the seventh trench 177. The first electrode layer 191, the dielectric layer 192, and the second electrode layer 193 together constitute a capacitor structure 190 as shown in FIG. 2.

It should be noted that in the embodiment of the present disclosure, the bit line 200 is formed first, and then the capacitor structure 190 is formed. In other embodiments, the capacitor structure 190 may be formed first, and then the bit line 200 is formed, which is not limited herein.

In the method for forming a semiconductor structure according to the embodiments of the present disclosure, because at least one end of the active pillar structure in the formed semiconductor structure along the Y-axis direction is provided with a trench with an opening facing the Y-axis direction, and the part of the active pillar structure adjacent to the trench constitutes the source/drain, such an arrangement can not only increase the distance between the gate structure and the drain, reducing the generation of GIDL, but also increase the contact area between the capacitor structure and the source/drain as well as between the bit line and the source/drain. This can reduce contact resistance and improve the response speed of the semiconductor structure. In addition, because the inner wall of the trench adjacent to the gate structure is provided with an isolation structure, such an arrangement can not only further reduce GIDL but also reduce the parasitic capacitance between the gate structure and the capacitor structure and between the gate structure and the bit line, thereby reducing the power consumption of the semiconductor structure.

The semiconductor structure formed by the method according to the embodiment of the present disclosure is similar to the semiconductor structure according to the embodiment described above. For technical features that are not disclosed in detail in the embodiment of the present disclosure, reference can be made to the embodiment described above for understanding, and details are not described here again.

In the embodiments provided in the present disclosure, it should be understood that the disclosed structure and method may be implemented in a non-targeted manner. The structural embodiments described above are merely illustrative. For example, the division into the units is only a logical functional division, and in actual implementation, there may be other division manners. For example, a plurality of units or modules may be combined, or may be integrated into another system; or some features may be ignored or not implemented. In addition, the various components shown or discussed are coupled or directly coupled to each other.

The features disclosed in the method or structural embodiments provided in the present disclosure may be combined in any manner if without conflict to obtain new method embodiments or structural embodiments.

The foregoing descriptions are only some embodiments of the present disclosure, but the scope of the present disclosure is not limited thereto. Changes or substitutions that any one skilled in the art can easily think of within the technical scope disclosed by the present disclosure shall all fall within the protection scope of the present disclosure. Therefore, the protection scope of the present disclosure shall be defined by the protection scope of the claims.

### INDUSTRIAL APPLICABILITY

The embodiments of the present disclosure provide a semiconductor structure. The semiconductor structure includes: a substrate; word line structures located on the substrate and spaced apart along a first direction, each word line structure including a plurality of gate structures spaced apart sequentially along a third direction; a plurality of active pillar structures, disposed on the outer wall of each gate structure, where at least one end of each active pillar structure along a second direction is provided with a trench with an opening facing the second direction; the part of the active pillar structure surrounding the gate structure constitutes a channel structure, and the part of the active pillar structure, located on both sides of the channel structure along the second direction and adjacent to the trench, constitutes the source/drain; and an isolation structure, located on the inner wall of the trench adjacent to the gate structure. Because at least one end of the active pillar structure along the second direction is provided with a trench with an opening facing the second direction, and the part of the active pillar structure adjacent to the trench constitutes the source/drain, such an arrangement can not only increase the distance between the gate structure and the drain, reducing the generation of GIDL, but also increase the contact area between the capacitor structure and the source/drain as well as between the bit line and the source/drain. This can reduce contact resistance and improve the response speed of the semiconductor structure. In addition, because the inner wall of the trench adjacent to the gate structure is provided with an isolation structure, such an arrangement can not only further reduce GIDL but also reduce the parasitic capacitance between the gate structure and the capacitor structure and between the gate structure and the bit line, thereby reducing the power consumption of the semiconductor structure.

What is claimed is:

1. A semiconductor structure, comprising:
a substrate;
word line structures located on the substrate and spaced apart along a first direction, wherein each of the word line structures comprises a plurality of gate structures spaced apart sequentially along a third direction;
a plurality of active pillar structures, disposed on an outer wall of each of the plurality of gate structures, wherein at least one end of each of the plurality of active pillar structures along a second direction is provided with a trench with an opening facing the second direction; a part of the active pillar structure surrounding the gate structure constitutes a channel structure, and a part of the active pillar structure, located on both sides of the channel structure along the second direction and adjacent to the trench, constitutes a source/drain; and
an isolation structure, located on an inner wall of the trench adjacent to the gate structure, wherein
the first direction intersects with the second direction and is located in a plane in which the substrate is located; the third direction intersects with the plane in which a surface of the substrate is located.

2. The semiconductor structure according to claim 1, wherein the trench comprises a first trench and a second trench located respectively at both ends of the active pillar structure along the second direction;
the isolation structure comprises a first isolation structure and a second isolation structure, wherein
the first isolation structure is located on an inner wall of the first trench adjacent to the gate structure, and the second isolation structure is located on an inner wall of the second trench adjacent to the gate structure.

3. The semiconductor structure according to claim 1, wherein a side wall of the word line structure in a cross-section along the third direction is serrated, and the word line structure comprises the gate structure and a recessed part alternately arranged sequentially along the third direction; a dimension of the gate structure along the second direction is greater than a dimension of the recessed part along the second direction, and a dimension of the gate structure along the first direction is greater than a dimension of the recessed part along the first direction.

4. The semiconductor structure according to claim 2, wherein the source/drain comprises a first source/drain and a second source/drain which are located at both ends of the active pillar structure along the second direction,
wherein a part of the active pillar structure adjacent to the first trench constitutes the first source/drain, and a part of the active pillar structure adjacent to the second trench constitutes the second source/drain.

5. The semiconductor structure according to claim 4, further comprising: a bit line and a capacitor structure, wherein
the bit line is connected to the first source/drain and is embedded in the first trench, contacting the first isolation structure; and
the capacitor structure is connected to the second source/drain and is embedded in the second trench, contacting the second isolation structure.

6. The semiconductor structure according to claim 5, further comprising: a spacer layer, wherein
the spacer layer is located between a plurality of the bit lines arranged along the third direction, between a plurality of the capacitor structures arranged along the third direction, and between a plurality of the active pillar structures arranged along the third direction.

7. The semiconductor structure according to claim 5, wherein the bit line extends along the first direction, and a row of the bit lines arranged along the first direction are interconnected;
the plurality of bit lines arranged along the third direction form a staircase structure.

8. The semiconductor structure according to claim 2, wherein the gate structure comprises a gate insulating layer; a thickness of the first isolation structure and the second isolation structure is greater than a thickness of the gate insulating layer.

9. The semiconductor structure according to claim 2, wherein the first isolation structure and the second isolation structure comprise silicon oxide, silicon oxynitride, or an air gap.

10. The semiconductor structure according to claim 1, further comprising a first insulating structure, wherein the first insulating structure is located between adjacent active pillar structures along the first direction.

11. The semiconductor structure according to claim 10, wherein a material of the first insulating structure is a low-k dielectric material.

12. The semiconductor structure according to claim 6, further comprising a second insulating structure, wherein the second insulating structure is located between the substrate and the spacer layer.

13. A method for forming a semiconductor structure, comprising:
providing a substrate, wherein a stacked structure is formed on the substrate; a projection of the stacked structure on the substrate is comb-shaped; the stacked structure comprises a first region and a second region which are arranged along a second direction; the second region comprises a plurality of sub-regions spaced apart along a first direction;
forming word line structures that extend along a third direction and penetrate through the plurality of sub-regions, wherein each of the word line structures comprises a plurality of gate structures spaced apart sequentially along the third direction;
forming a plurality of active pillar structures that surround the plurality of gate structures and are spaced apart, wherein at least one end of each of the plurality of active pillar structures along the second direction is provided with a trench with an opening facing the second direction; a part of the active pillar structure surrounding the gate structure constitutes a channel structure, and a part of the active pillar structure, located on both sides of the channel structure along the second direction and adjacent to the trench, constitutes a source/drain; and
forming an isolation structure on an inner wall of the trench adjacent to the gate structure, wherein
the first direction intersects with the second direction and is parallel to a plane in which the substrate is located, and the third direction is perpendicular to the plane in which the substrate is located.

14. The method according to claim 13, wherein the stacked structure comprises a spacer layer, a first sacrificial layer, a second sacrificial layer, and the first sacrificial layer, which are alternately and cyclically arranged along the third direction; forming the word line structures that extend along the third direction and penetrate through the plurality of sub-regions comprises:
etching each of the plurality of sub-regions to form a third trench extending along the third direction, the third trench exposing the spacer layer at a lowest level;
forming a first initial active pillar structure on part of an inner wall of the third trench, the first initial active pillar structure being partially or fully embedded in the first sacrificial layer; and
forming the word line structure in the third trench provided with the first initial active pillar structure.

15. The method according to claim 14, wherein forming the plurality of active pillar structures that surround the plurality of gate structures and are spaced apart comprises:
removing a part of the first initial active pillar structure that extends along the first direction into a space between the second sacrificial layer and the spacer layer to form the active pillar structure,
wherein a remaining part of the first initial active pillar structure embedded between the second sacrificial layer and the spacer layer constitutes the source/drain; and
a region between a remaining part of the first initial active pillar structure that extends into the space between the second sacrificial layer and the spacer layer, and the first initial active pillar structure located on a side wall of the second sacrificial layer, forms the trench.

16. The method according to claim 14, wherein the trench comprises a first trench and a second trench located respectively at both ends of the active pillar structure along the second direction; the isolation structure comprises a first isolation structure located on an inner wall of the first trench adjacent to the gate structure, as well as a second isolation structure located on an inner wall of the second trench adjacent to the gate structure; forming the isolation structure on the inner wall of the trench adjacent to the gate structure comprises:
removing the second sacrificial layer between the channel structures to form the first trench and the second trench; and
forming the first isolation structure and the second isolation structure respectively on the inner walls of the first trench and the second trench adjacent to the gate structure.

17. The method according to claim 16, wherein the source/drain comprises a first source/drain and a second source/drain located at both ends of the active pillar structure along the second direction, and a part of the active pillar structure adjacent to the first trench constitutes the first source/drain; the method further comprises:
removing the second sacrificial layer in the stacked structure while forming the first trench and the second trench, to form a fourth trench and a fifth trench, wherein the fourth trench encloses the first trench, and the fifth trench encloses the second trench;
after or while forming the first isolation structure and the second isolation structure, removing the first sacrificial layer on one side close to the first region along the first direction in the first region and the second region, to form a sixth trench, wherein the sixth trench encloses the fourth trench; and
forming a bit line in contact with the first source/drain in the sixth trench.

18. The method according to claim 17, wherein a part of the active pillar structure adjacent to the second trench constitutes the second source/drain; the method further comprises:
removing a remaining first sacrificial layer in the stacked structure to form a seventh trench, wherein the seventh trench encloses the fifth trench; and
forming a capacitor structure in contact with the second source/drain in the seventh trench.

19. The method according to claim 14, wherein forming the first initial active pillar structure on part of the inner wall of the third trench comprises:
forming a second initial active pillar structure on the inner wall and a bottom of the third trench; and
removing the second initial active pillar structure at the bottom of the third trench and on a side wall of the spacer layer to form the first initial active pillar structure.

20. The method according to claim 14, wherein etching each of the plurality of sub-regions to form the third trench extending along the third direction comprises:
etching the sub-region until the spacer layer at the lowest level is exposed, thereby forming an eighth trench extending along the third direction; and
through the eighth trench, laterally etching to remove part of the first sacrificial layer and part of the second sacrificial layer, thereby forming the third trench, wherein the third trench encloses the eighth trench and is serrated; a dimension of the third trench between the first sacrificial layers is greater than a dimension of the third trench between the second sacrificial layers.
